(19) United States
(12) Patent Application Publication
(10) Pub. No.: US 2020/0194418 A1
(43) Pub. Date: Jun. 18, 2020

(54) INVERTER STRUCTURE WITH DIFFERENT SIZED CONTACTS

(71) Applicant: GLOBALFOUNDRIES INC., Grand Cayman (KY)

(72) Inventors: Seong Yeol Mun, Cohoes, NY (US); Chung Foong Tan, Ballston Spa, NY (US); Peter P. Steinmann, Albany, NY (US)

(21) Appl. No.: 16/222,161

(22) Filed: Dec. 17, 2018

(51) Int. Cl. H01L 27/02; H01L 27/092

(52) U.S. Cl. CPC H01L 27/0207; H01L 27/092

(57) ABSTRACT

An inverter structure includes a p-type field effect transistor (PFET) including a PFET source, a PFET drain and a PFET gate; a n-type field effect transistor (NFET) including an NFET source, an NFET drain and an NFET gate. The NFET is adjacent to the PFET, and the PFET drain and the NFET drain form an output node and the PFET gate and the NFET gate are electrically connected to form an input node. A zero via layer includes: at least one first contact electrically coupled to the PFET source, at least one second contact electrically coupled to the NFET source, and at least one third contact electrically coupled to the output node. Each third contact has a smaller width in a fin-length direction than each first contact and each second contact to improve RC delay and overall performance.

### BACKGROUND

The present disclosure relates to integrated circuit fabrication, and more specifically, to an inverter structure including different sized contacts in the same layer to improve resistance-capacitance (RC) delay and overall performance.

Advanced manufacturing of ICs requires formation of individual circuit elements, e.g., transistors such as field-effect-transistors (FETs) and the like, based on specific circuit designs. A FET generally includes source, drain, and gate regions. The gate region is placed between the source and drain regions and controls the current through a channel region (often shaped as a semiconductor fin) between the source and drain regions. Gates may be composed of various metals and often include a work function metal which is chosen to create desired characteristics of the FET. Transistors may be formed over a substrate and may be electrically isolated with an insulating dielectric layer, e.g., inter-level dielectric (ILD) layer. Contacts may be formed to each of the source, drain, and gate regions through the dielectric layer in order to electrically connect the transistors to other circuit elements that may be formed subsequent to the transistors in other metal levels.

Fin-type field effect transistors (“FinFETs”) have become increasingly widespread because FinFETs offer better electrostatic control over the behavior in the channel than planar FETs. FinFETs are formed by creating a number of semiconductor fins on a substrate and placing a gate conductor perpendicularly across the fins. A FinFET is created by the gate forming a channel region below the gate in the fin, and source/drain regions formed in the fin aside the gate.

A standard cell inverter structure can be used as part of a number of IC structures, e.g., in a ring oscillator. A standard cell inverter structure includes an interconnected n-type FET (NFET) and a p-type FET (PFET). More particularly, the NFET and PFET in a standard cell inverter structure have their drains interconnected and their gates interconnected. The standard cell inverter structure performance is sensitive to parasitic capacitance (CMOL) at a voltage output (Vout), and external resistance (REXT) at the PFET source (VDD) or the NFET source (VSS) nodes. As IC structures have continued to be miniaturized, the contact to gate space becomes narrower, increasing the parasitic capacitance and increasing the external resistance. As the parasitic capacitance and the external resistance increase, it degrades the resistance-capacitance (RC) delay and the overall performance of the standard cell inverter structure.

### SUMMARY

A first aspect of the disclosure is directed to an inverter structure, comprising: a p-type field effect transistor (PFET) including a PFET source, a PFET drain and a PFET gate; a n-type field effect transistor (NFET) including an NFET source, an NFET drain and an NFET gate, wherein the NFET is adjacent to the PFET, and the PFET drain and the NFET drain form an output node and the PFET gate and the NFET gate are electrically connected to form an input node; a zero via layer including: at least one first contact electrically coupled to the PFET source, at least one second contact electrically coupled to the NFET source, and at least one third contact electrically coupled to the output node, wherein each third contact has a smaller width in a fin-length direction than each first contact and each second contact.

A second aspect of the disclosure includes an inverter structure, comprising: a p-type field effect transistor (PFET) including a PFET source (V_{DD}), a PFET drain and a PFET gate; a n-type field effect transistor (NFET) including an NFET source (V_{SS}), an NFET drain and an NFET gate, wherein the PFET drain and the NFET drain form an output node (Vₒᵤₜ); at least one first contact electrically coupled to the PFET source (V_{DD}); at least one second contact electrically coupled to the NFET source (V_{SS}); and at least one third contact electrically coupled to the output node (Vₒᵤₜ), wherein each third contact has a smaller width in a fin-length direction than each first contact and each second contact, wherein each contact is in the same layer.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a plan view of a conventional standard cell inverter structure.

FIG. 2 shows a plan view of a standard cell inverter structure according to embodiments of the disclosure.

FIG. 3 shows a cross-sectional view of the inverter structure through a fin along line 3-3 in FIG. 2.

FIG. 4 shows a cross-sectional view of the inverter structure through a fin along line 4-4 in FIG. 2.

FIG. 5 shows a schematic cross-sectional view of the inverter structure through a fin along line 3-3 and 4-4 in FIG. 2, and including a metal layer thereover.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

Embodiments of the disclosure provide an inverter structure including different sized contacts to improve resistance-capacitance (RC) delay and overall performance. An inverter structure includes a p-type field effect transistor (PFET) and an n-type field effect transistor (NFET), each including respective sources, drains and gates. The inverter structure according to embodiments of the disclosure provides a wider contact compared to conventional contacts at a PFET source (V_{DD}) and NFET source (V_{SS}) to reduce external resistance (Rₑₓₜ), reducing gate-source voltage (V_{GS}) drop and improving overall performance. In addition, the inverter structure has a less wide contact compared to conventional contacts at an output (Vout)(i.e., common drain node of the PFET and the NFET), which reduces parasitic capacitance. Since parasitic capacitance (CMOL) is about 15% of effective capacitance, controlling parasitic capacitance at the output node can significantly improve RC delay. Further, because capacitance attributable to the output node is doubled by the Miller effect, the capacitance reduction in the output has a large impact on total parasitic capacitance. In electronics, the Miller effect accounts for an increase in the effective capacitance of an inverter structure due to magnification of the effect of capacitance between the output node and the input node. Combining the two different sized contacts can significantly improve standard cell inverter structure performance by RC delay.

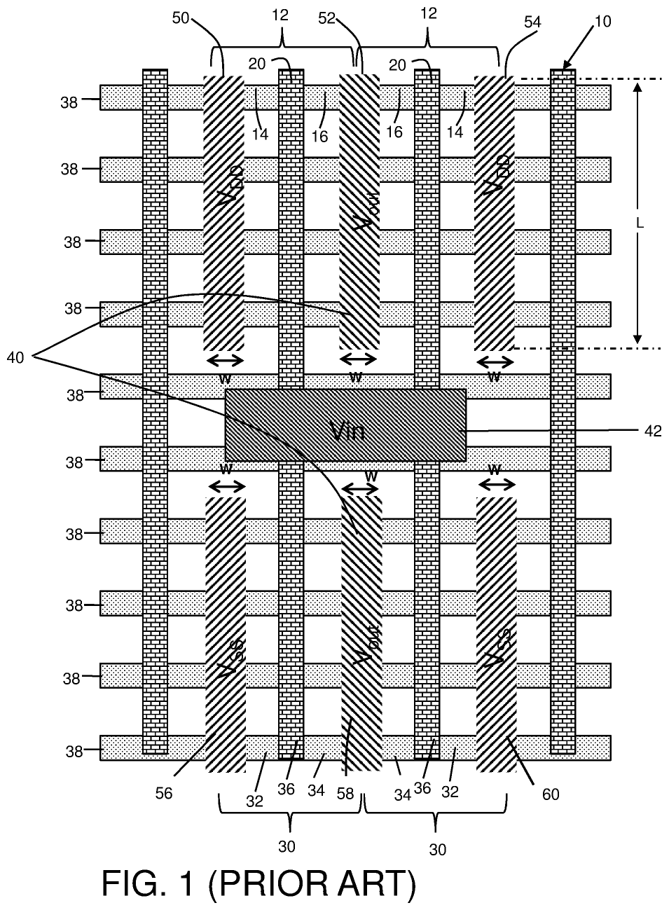

FIG. 1 shows a conventional inverter structure 10 including a p-type field effect transistor (PFET) 12 including a PFET source 14, a PFET drain 16 and a PFET gate 20 (shared). Inverter structure 10 also includes an n-type field effect transistor (NFET) 30 including an NFET source 32, an NFET drain 34 and an NFET gate 36 (shared). NFET 30 and PFET 12 are formed using one or more semiconductor fins 38 (e.g., four) which are doped with appropriate dopants to form the necessary source/drain regions in a known fashion. Gates 20 and 36 extend perpendicularly over fins 38 to form channel regions for FETs 30 and 12, in a known fashion.

PFET drain 16 and NFET drain 34 are electrically coupled (e.g., by coupling contacts 52, 58 using metal layers not shown) to form an output node 40 (Vₒᵤₜ). PFET gate 20 and NFET gate 26 are electrically connected to form an input node 42 (Vᵢₙ). As illustrated, contacts 50, 52, 54, 56, 58 and 60 couple to PFET source 14, PFET drain 16, PFET gate 20, NFET source 32, NFET drain 34 and NFET gate 36, respectively. Contacts 50, 52, 54 (shown), and 56, 58, 60 may have a length L running up and down on the page that may vary, but all, per conventional processing, have an identical width W. A critical dimension of width W (along with most other dimensions of the transistors) must meet a design rule for a particular technology node, i.e., size of wiring for the integrated circuit including the inverter structure. That is, width W, i.e., extending in a fin-length direction, must fall within a particular range. Typically, for a particular technology node, width W is not configured to reach a minimum or maximum of the design rule range, and is typically somewhere in the middle of the range. For example, for a given technology node, width W may need to be within a range of 18 nanometers to 24 nanometers, but may be at 20 nanometers.

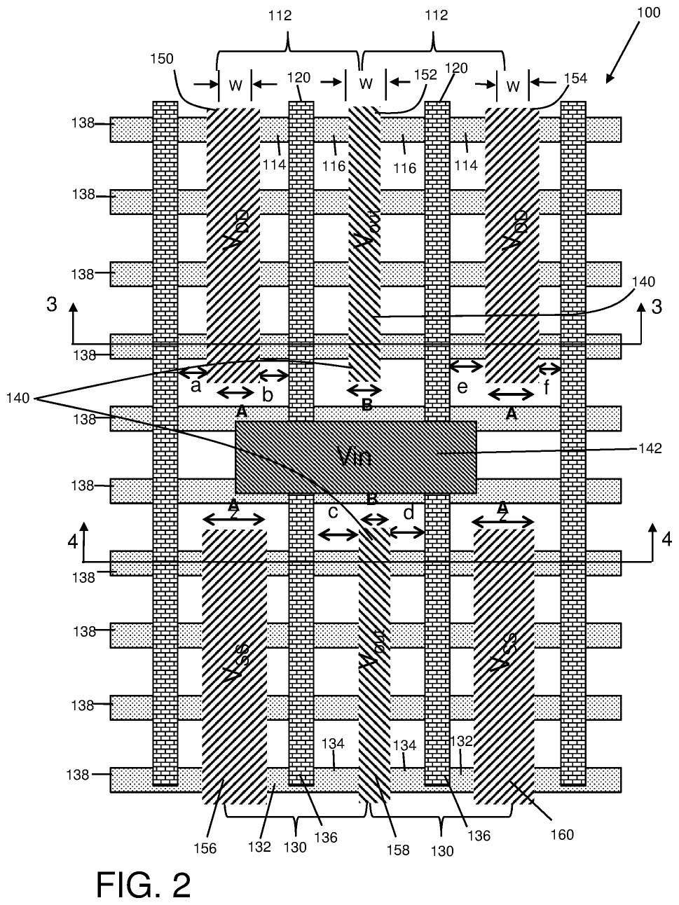

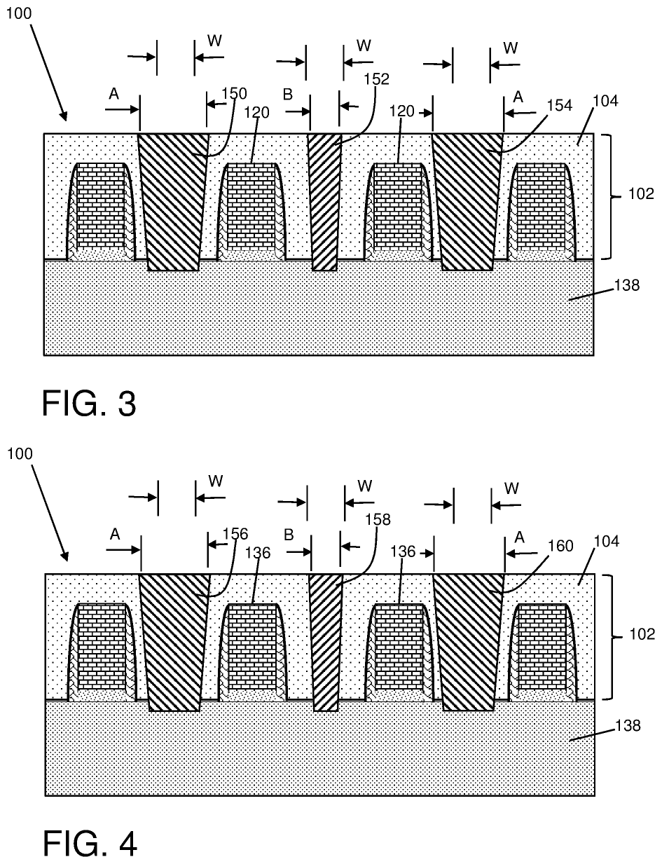

In accordance with embodiments of the disclosure, the width of contacts are either increased or decreased within their design rule range to decrease RC delay and overall performance. FIG. 2 shows a plan view of a standard cell inverter structure 100 according to embodiments of the disclosure. Also, FIG. 3 shows a cross-sectional view of the inverter structure through a fin 138 along line 3-3 in FIG. 2, and FIG. 4 shows a cross-sectional view of the inverter structure through a fin 138 along line 4-4 in FIG. 2. It is noted that FIGS. 3 and 4 show a cross-section in a PFET and an NFET of inverter structure 100, respectively, but are substantially similar otherwise.

Inverter structure 100 includes PFET 112 including a PFET source 114, a PFET drain 116 and a PFET gate 120 (shared). Inverter structure 100 also includes NFET 130 including an NFET source 132, an NFET drain 134 and an NFET gate 136 (shared). In the drawings, NFET 130 and PFET 112 are each shown with double gates, it is understood however that the teachings of the disclosure are applicable to single gate transistors. In any event, NFET 130 is adjacent to PFET 112, i.e., they are formed in close proximity. NFET 130 and PFET 112 are formed using one or more semiconductor fins 138 (e.g., four) which are doped with appropriate dopants to form the necessary source/drain regions. Gates 120 and 136 extend perpendicularly over fins 138 to form channel regions for FETs 130 and 112 (in fins 138 under the gates), in a known fashion.

PFET drain 116 and NFET drain 134 are electrically coupled (e.g., by coupling contacts 152, 158 using metal layers not shown) to form an output node 140 (Vₒᵤₜ). PFET gate 120 and NFET gate 136 are electrically connected to form an input node 142 (Vᵢₙ). As illustrated, contacts 150, 152, 154, 156, 158, 160 couple to PFET source 114, PFET drain 116, PFET gate 120, NFET source 132, NFET drain 134 and NFET gate 136, respectively. Contacts 150-160 are part of a zero via layer 102 (FIG. 3) including any now known or later developed interlayer dielectric layer 104.

Contacts 150-160 may have a length L running up and down on the page. Inverter structure 100 includes zero via layer 102 (FIG. 3) including at least one first contact 152, 154 electrically coupled to PFET source 114 (V_{DD}), and at least one second contact 158, 160 electrically coupled to NFET source 132 (V_{SS}). Further, inverter structure 100 may include at least one third contact 152, 158 electrically coupled to output node 140 (Vₒᵤₜ). Contacts 150-160 are all in the same layer.

In contrast to conventional inverter structures, each third contact 152, 158 has a smaller width B in a fin-length direction than each first contact 150, 154 and each second contact 156, 160, i.e., with widths A. In this case, width A may be increased relative to a conventional FinFET from width W (FIG. 1) to, for example, 24 nanometers by decreasing dimensions a, b, e and f. Similarly, width B may be decreased relative to a conventional FinFET to, for example, 18 nanometers by increasing dimensions c and d. The changed dimensions are changed within the limitations of design rules for a respective technology node. That is, the dimensions are pushed toward the outer limits from their normally middle of the range values. The difference in critical dimension between the larger and smaller contacts, e.g., 6 nanometers, is greater than a nominal critical dimension size variation (e.g., +/−1 nanometer) for the layer.

In operation, voltage at contact(s) 150, 154 (V_{DD}) and contact(s) 156, 160 (V_{SS}) are increased compared to inverter structure 10 (FIG. 1), which reduces external resistance. Further, voltage at contact(s) 152, 158, i.e., output voltage (Vₒᵤₜ), is decreased, reducing parasitic capacitance. This latter reduction can have a significant impact on RC delay because the capacitance connected to voltage output 140 is doubled by the Miller effect. In any event, the RC delay is reduced, resulting in performance improvement of inverter structure 100 compared to conventional inverter structures.

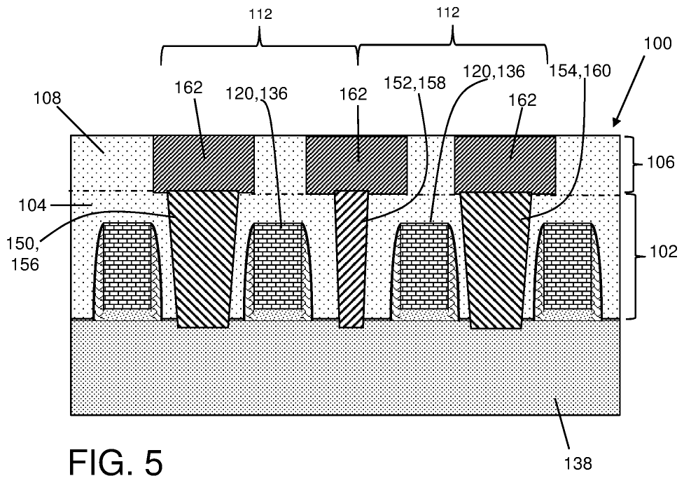

FIG. 5 shows a schematic cross-sectional view of inverter structure 100 through a fin 138 along line 3-3 and 4-4 in FIG. 2. As illustrated, inverter structure 100 may also include a metal layer 106 over zero via layer 102. Metal layer 106 may include a metal wire 162 embedded in a dielectric 108 to each of the first contacts 150, 154, second contacts 156, 160, and third contacts 152, 158. Middle metal wire 162 may couple contact 152 and 158 to create output node 140.

Inverter structure 100 may be formed using any now known or later developed semiconductor fabrication techniques. Contacts 150-160 may be formed, for example, using a single Damascene process, or may be formed with metal wires 162 using a dual damascene process. Contacts 150-160 may include any now known or later developed conductive materials such as but not limited to copper, tungsten or aluminum, and may include any appropriate refractory metal liner (not shown).

Suitable dielectric materials for ILD layers 102, 106 may include but are not limited to: carbon-doped silicon dioxide materials; fluorinated silicate glass (FSG); organic polymeric thermoset materials; silicon oxycarbide; SiCOH dielectrics; fluorine doped silicon oxide; spin-on glasses; silsesquioxanes, including hydrogen silsesquioxane (HSQ), methyl silsesquioxane (MSQ) and mixtures or copolymers of HSQ and MSQ; benzocyclobutene (BCB)-based polymer dielectrics, and any silicon-containing low-k dielectric. Examples of spin-on low-k films with SiCOH-type composition using silsesquioxane chemistry include HOSP™ (available from Honeywell), JSR 5109 and 5108 (available from Japan Synthetic Rubber), Zirkon™ (available from Shipley Microelectronics, a division of Rohm and Haas), and porous low-k (ELk) materials (available from Applied Materials). Examples of carbon-doped silicon dioxide materials, or organosilanes, include Black Diamond™ (available from Applied Materials) and Coral™ (available from Lam Research). An example of an HSQ material is FOx™ (available from Dow Corning).

Integrated circuit chips including an inverter structure as described herein can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An inverter structure, comprising:
a p-type field effect transistor (PFET) including a PFET source, a PFET drain and a PFET gate;
a n-type field effect transistor (NFET) including an NFET source, an NFET drain and an NFET gate,
wherein the NFET is adjacent to the PFET, and the PFET drain and the NFET drain form an output node and the PFET gate and the NFET gate are electrically connected to form an input node;
a zero via layer including:
at least one first contact electrically coupled to the PFET source,
at least one second contact electrically coupled to the NFET source, and
at least one third contact electrically coupled to the output node,
wherein each third contact has a smaller width in a fin-length direction than each first contact and each second contact.

2. The inverter structure of claim 1, further comprising a metal layer over the zero via layer, the metal layer including a metal wire embedded in a dielectric to each of the first, second and third contacts.

3. An inverter structure, comprising:
a p-type field effect transistor (PFET) including a PFET source (V_{DD}), a PFET drain and a PFET gate;
a n-type field effect transistor (NFET) including an NFET source (V_{SS}), an NFET drain and an NFET gate,
wherein the PFET drain and the NFET drain form an output node (Vₒᵤₜ);
at least one first contact electrically coupled to the PFET source (V_{DD});
at least one second contact electrically coupled to the NFET source (V_{SS}); and
at least one third contact electrically coupled to the output node (Vₒᵤₜ),
wherein each third contact has a smaller width in a fin-length direction than each first contact and each second contact, wherein each contact is in the same layer.

4. The inverter structure of claim 3, further comprising a metal layer over the zero via layer, the metal layer including a metal wire embedded in a dielectric to each of the first, second and third contacts.
